(19) United States
(12) Patent Application Publication
(10) Pub. No.: US 2003/0000567 A1
(43) Pub. Date: Jan. 2, 2003

(54) Solar construction board and solar louver made therefrom

(76) Inventor: Kuo-Yuan Lynn, Tainan City (TW)

Correspondence Address: FROMMER LAWRENCE & HAUG LLP, 745 Fifth Avenue, New York, NY, 10151, US

(21) Appl. No.: 10/179,345

(22) Filed: Jun. 25, 2002

(30) Foreign Application Priority Data
Jun. 27, 2001 (TW) 090210786

(51) Int. Cl. H01L 31/00

(52) U.S. Cl. 136/246

(57) ABSTRACT

A solar construction board includes a board, a solar energy collector mounted on the board and including at least a heating tube which is filled with a first fluid medium therein so as to absorb solar energy and transfer the absorbed energy to the first fluid medium when exposed to solar radiation, and a solar cell unit that includes at least a solar cell which is securely attached to the board so as to generate electrical current when exposed to solar radiation.

### CROSS-REFERENCE TO RELATED APPLICATION

This application claims priority of Taiwan patent Application No. 90210786, filed on Jun. 27, 2001.

### BACKGROUND OF THE INVENTION

1. Field of the Invention

This invention relates to a solar construction board and a solar louver made therefrom.

2. Description of the Related Art

It is known in the art that solar energy can be converted to useful heat by using a collector to absorb solar radiation. For instance, the collector can be mounted on a roof of a building, and the collected heat can be used for heating the interior of the building. Another form of energy that the solar energy can be converted to is electricity via photovoltaic effect of a solar cell which is capable of generating electrical current upon exposure to solar radiation.

### SUMMARY OF THE INVENTION

One object of the present invention is to provide a solar construction board that integrates the aforesaid collector and solar cell into a construction module for buildings.

Another object of the present invention is to provide a solar louver that is made from the aforesaid solar construction board.

According to one aspect of the present invention, a solar construction board comprises: a supporting board having top and bottom surfaces; a solar energy collector that is mounted securely on the top surface of the supporting board and that includes at least a heating tube which is filled with a first fluid medium therein so as to absorb solar energy and transfer the absorbed energy to the first fluid medium when exposed to solar radiation; and a solar cell unit that includes at least a solar cell which is securely attached to the top surface of the supporting board so as to generate electrical current when exposed to solar radiation.

According to another aspect of the present invention, a solar louver comprises: a frame having two opposite sides that extend in a longitudinal direction; a plurality of aligned slanted boards which are mounted pivotally in the frame, which are aligned in a head-to-tail manner in the longitudinal direction, and which are turnable between opened and closed positions; a plurality of solar cells which are respectively attached to the slanted boards; a coupling unit pivoted to the slanted boards and movable in the longitudinal direction and in a transverse direction relative to the longitudinal direction so as to permit the slanted boards to be turnable between the opened and closed positions; and a driving unit connected to the coupling unit so as to move the coupling unit in the longitudinal and transverse directions.

### BRIEF DESCRIPTION OF THE DRAWINGS

In drawings which illustrate embodiments of the invention,

FIG. 1 is a perspective view of a preferred embodiment of a solar construction board of this invention;

FIG. 2 is a partly sectional view of the solar construction board of FIG. 1;

FIG. 3 is a schematic view of the preferred embodiment of a solar louver of this invention;

FIG. 4 is a side view of the solar louver of FIG. 3 at a closed position;

FIG. 5 is a side view of the solar louver of FIG. 3 at an opened position;

FIG. 6 is a partly sectional view of a second preferred embodiment of the solar louver modified from the embodiment of FIG. 3 at a closed position;

FIG. 7 is a partly sectional view of the solar louver of FIG. 6 at an opened position; and

FIG. 8 is a top view to illustrate how the solar louver of FIG. 3 or FIG. 6 can be used to serve as a roof window on a roof.

### DETAILED DESCRIPTION OF THE PREFERRED EMBODIMENTS

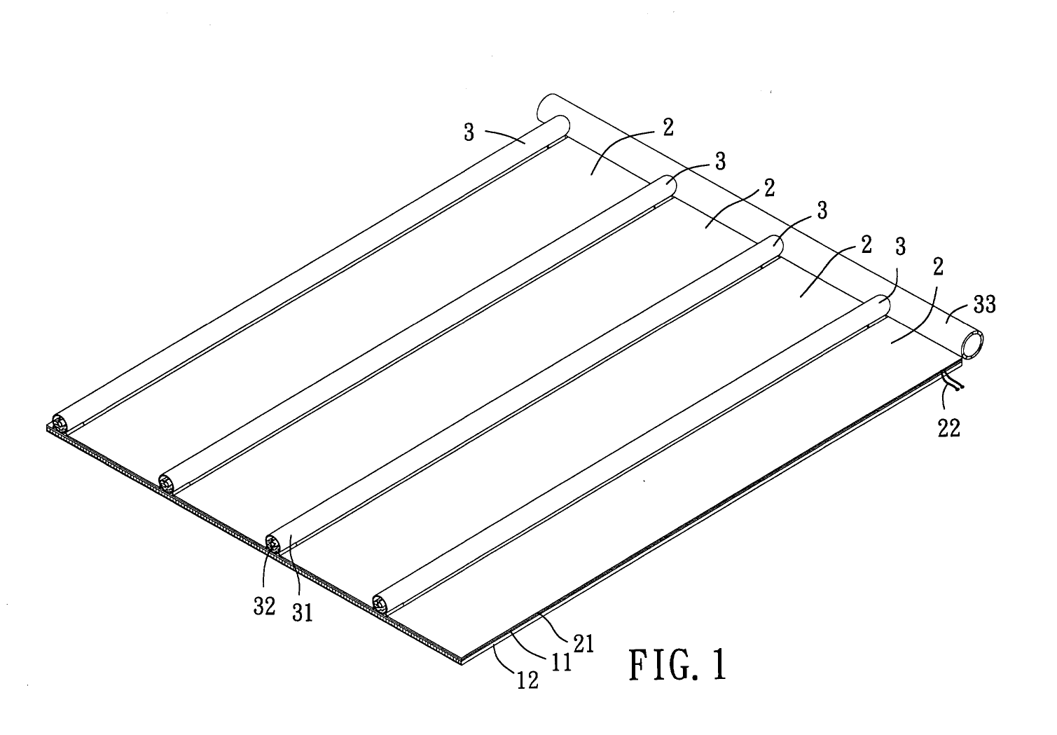

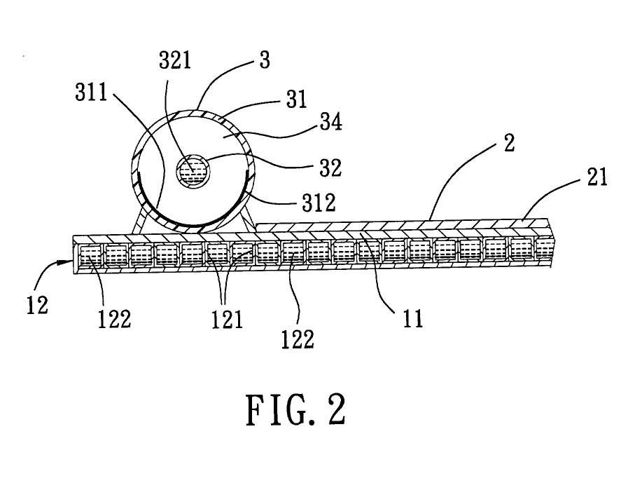

FIGS. 1 and 2 illustrate a preferred embodiment of a solar construction board of this invention for construction purposes, such as for roofing of a building (not shown). The solar construction board includes: a supporting board 11 having top and bottom surfaces; a solar energy collector 3 that is mounted securely on the top surface of the supporting board 11 and that includes at least a heating tube 32 (there are four heating tubes shown in FIG. 1) which is filled with a first fluid medium 321 therein so as to absorb solar energy and transfer the absorbed energy to the first fluid medium 321 when exposed to solar radiation; and a solar cell unit 2 that includes at least a solar cell 21 (there are four solar cells 21 shown in FIG. 1) which is securely attached to the top surface of the supporting board 11 so as to generate electrical current when exposed to solar radiation. A connecting pipe 33 is connected to and is in fluid communication with the heating tubes 32 so as to transport the first fluid medium 321 to a storing space (not shown) in the building.

A thermal insulator unit 12 is mounted securely on the bottom surface of the supporting board 11 so as to retard the radiation of heat from the bottom surface of the supporting board 11. The thermal insulator unit 12 includes a plurality of juxtaposed conduits 121 which are in fluid communication with each other and which are filled with a second fluid medium 122. The second fluid medium 122 absorbs heat from the supporting board 11 via heat conduction, and can be used for indoor temperature conditioning or providing warm water for swimming pools.

The solar energy collector 3 can optionally include a transparent tube 31 that coaxially surrounds and that cooperates with the heating tube 32 to define a chamber 34 therebetween and that has an inner surface. The chamber 34 is filled with a third fluid medium. The inner surface of the transparent tube 31 has a lower portion 312 that is coated with a reflective layer 311 of a reflective material so as to enhance energy absorbing effect of the heating tube 32. An electrical wire 22 is connected to the solar cells 21 for electrical output.

The first and second fluid mediums 321, 122 are preferably selected from a group consisting of water and air. The supporting board 11 is preferably made from a metal having high thermal conductivity.

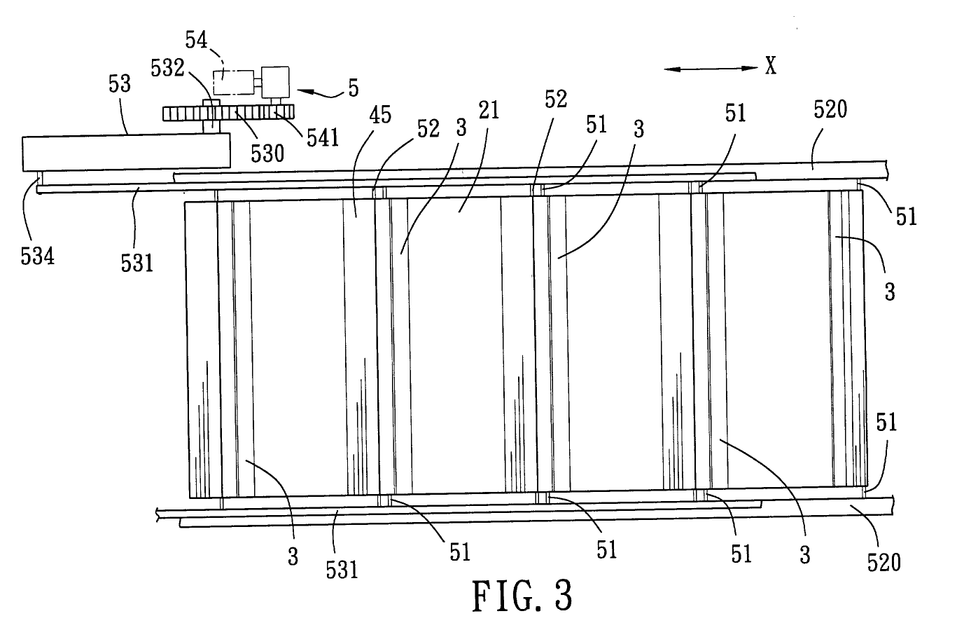

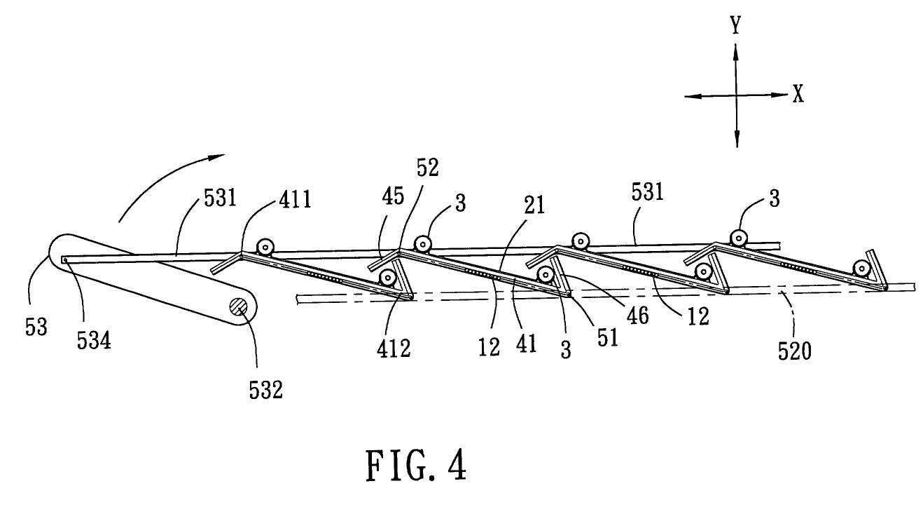

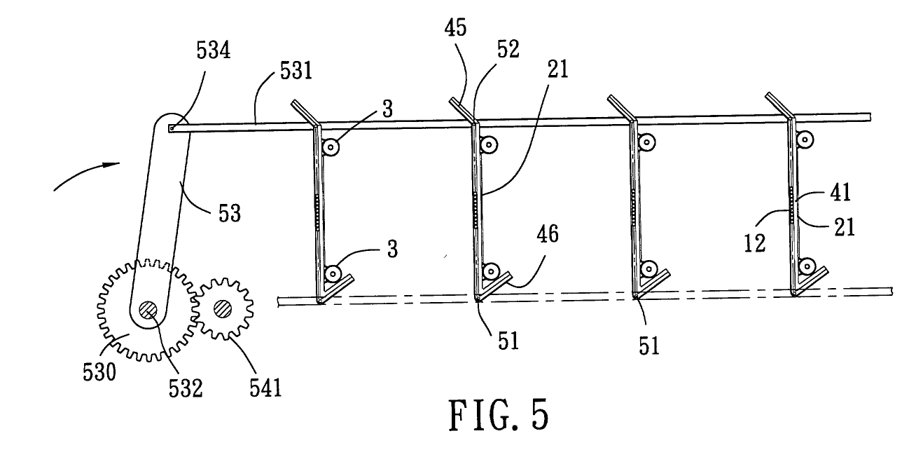

FIGS. 3 to 5 illustrate a preferred embodiment of a solar louver of this invention that is made from the aforesaid solar construction board of FIG. 1. The solar louver includes: a frame 520 that is adapted to be installed on a wall of a building (not shown) and that has two opposite sides extending in a longitudinal direction (X); a plurality of aligned slanted boards 41 which are mounted pivotally in the frame 520, which are aligned in a head-to-tail manner in the longitudinal direction (X), and which are turnable between opened and closed positions (see FIGS. 4 and 5); a plurality of solar cells 21 which are respectively attached to the slanted boards 41; a coupling unit pivoted to the slanted boards 41 and movable in the longitudinal direction (X) and in a transverse direction (Y) relative to the longitudinal direction (X) so as to permit the slanted boards 41 to be turnable between the opened and closed positions; and a driving unit 5 connected to the coupling unit so as to move the coupling unit in the longitudinal and transverse directions (X, Y).

Each of the slanted boards 41 has two opposite sides in the longitudinal direction (X), and opposite first and second ends 411, 412. The coupling unit includes a pair of parallel elongated rod-like links 531 that are respectively disposed at the opposite sides of the slanted boards 41 and that are offset from the opposite sides of the frame 520 in the transverse direction (Y). The first ends 411 of the slanted boards 41 are pivoted to the links 531 via pins 52. The second ends 412 of the slanted boards 41 are pivoted to the frame 520 via pins 51. The coupling unit further includes a lever 53 that has two opposite ends respectively connected to the driving unit 5 via a shaft 532 and to the links 531 via a pin 534 and that is turnable relative to the driving unit 5 so as to move the links 531 in the longitudinal and transverse directions (X, Y), thereby moving the slanted boards 41 between the opened and closed positions. The driving unit 5 includes a motor 54, an output gear 541 driven by the motor 54, and a driven gear 530 meshing with the output gear 541 and connected to the shaft 532 so as to turn the lever 53, which, in turn, moves the links 531 in the longitudinal and transverse directions (X, Y).

A board shade 45 extends inclinedly in a first inclined direction from the first end 411 of each of the slanted boards 41 toward the second end 412 of an adjacent one of the slanted boards 41. A board guide 46 extends inclinedly in a second inclined direction from the second end 412 of each of the slanted boards 41 toward the first end 411 of an adjacent one of the slanted boards 41 so that the board shade 45 of each of the slanted boards 41 and the board guide 46 of an adjacent one of the slanted boards 41 move toward each other when the slanted boards 41 move from the opened position to the closed position (see FIG. 4) so as to prevent rain and dust from entering into a building (not shown).

Two of the aforesaid solar energy collectors 3 of FIG. 1 can be mounted securely on the first and second ends 411, 412 of the slanted boards 41.

Each of the slanted boards 41 can be further integrated with the aforesaid insulator unit 12 of FIG. 1 which is attached to a bottom face of the slated boards 41 that is opposite to a respective one of the solar cells 21.

The solar construction board or the solar louver of this invention integrates the functions of a conventional construction board or a conventional louver with the functions of the solar cells 21 and the solar energy collector 3, and can be applied to many indoor-outdoor interface constructions.

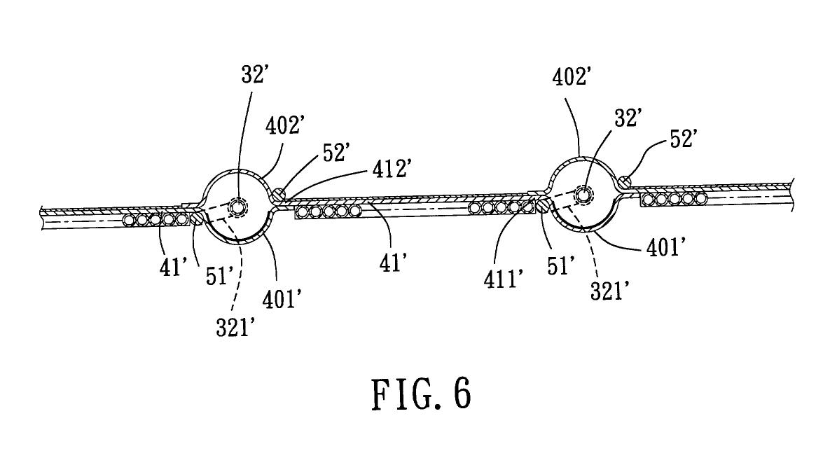

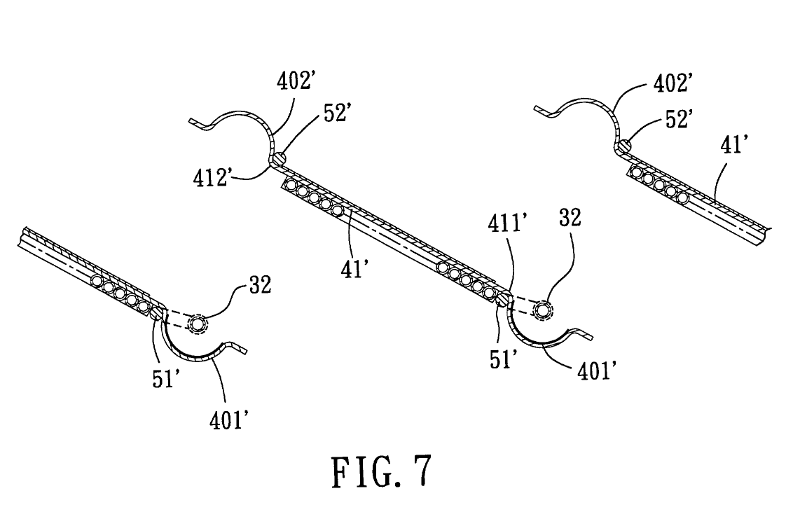

FIG. 6 illustrates a second preferred embodiment of the solar louver modified from the previous embodiment of FIG. 3 at a closed position. The solar louver is similar to the embodiment of FIG. 3, except that the board shed 45 and the board guide 46 in FIG. 4 are replaced with opposite transparent first and second circular halves 401′, 402′ which respectively extend from the first and second ends 411′, 412′ of each of the slanted boards 41′. The first circular half 401′ of each of the slanted boards 41′ complements the second circular half 402′ of an adjacent one of the slanted boards 41′ to form a circular tube that performs the same functions as the transparent tube 31 in FIG. 2. Preferably, each of the slanted boards 41′ is made from a transparent plastic material. The heating tubes 32′ in the circular tubes are supported by the respective pins 51′ via connecting members 321′. FIG. 7 illustrates the solar louver at an opened position (rotation of the slanted boards 41′ from the closed position to the opened position proceeds in a manner similar to that of the previous embodiment in FIGS. 4 and 5), wherein, the complementary first and second circular halves 401′ 402′ of the adjacent slanted boards 41′ are separated from each other. The modified construction of the solar louver of this embodiment facilitates cleaning of the first and second circular halves 401′, 402′ of the circular tubes.

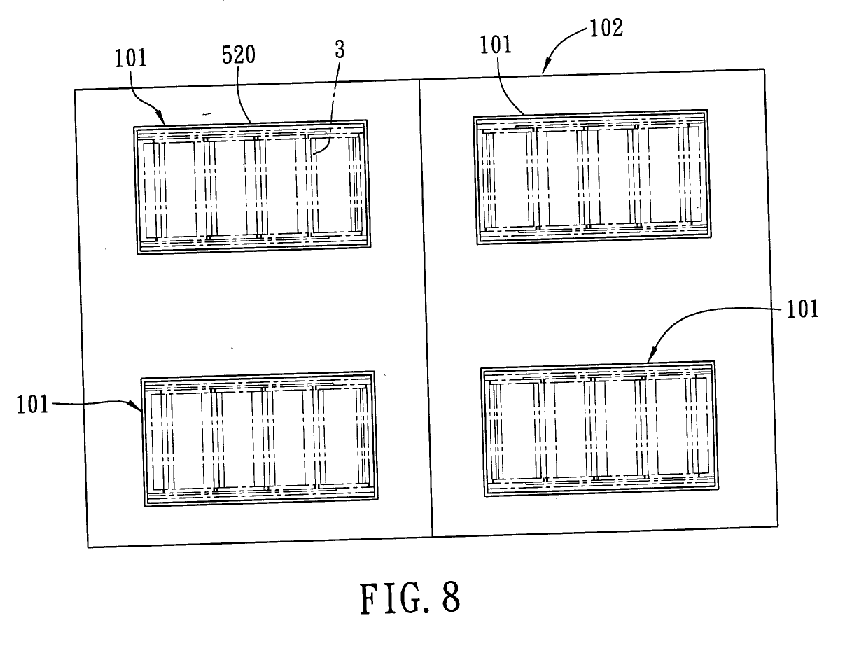

FIG. 8 illustrates how the solar louver of this invention can be used to serve as a roof window 101 on a roof 102.

With the invention thus explained, it is apparent that various modifications and variations can be made without departing from the spirit of the present invention. It is therefore intended that the invention be limited only as recited in the appended claims.

I claim:

1. A solar construction board comprising:
a supporting board having top and bottom surfaces;
a solar energy collector that is mounted securely on said top surface of said supporting board and that includes at least a heating tube which is filled with a first fluid medium therein so as to absorb solar energy and transfer the absorbed energy to said first fluid medium when exposed to solar radiation; and
a solar cell unit that includes at least a solar cell which is securely attached to said top surface of said supporting board so as to generate electrical current when exposed to solar radiation.

2. The solar construction board of claim 1, further comprising a thermal insulator unit that is mounted securely on said bottom surface of said supporting board so as to retard the radiation of heat from said bottom surface of said supporting board.

3. The solar construction board of claim 2, wherein said thermal insulator unit includes a plurality of juxtaposed conduits which are in fluid communication with each other and which are filled with a second fluid medium.

4. The solar construction board of claim 1, wherein said solar energy collector further includes a transparent tube that surrounds and that cooperates with said heating tube to define a chamber therebetween and that has an inner surface, said chamber being filled with a third fluid medium, said inner surface having a lower portion that is coated with a layer of a reflective material so as to enhance energy absorbing effect of said heating tube.

5. The solar construction board of claim 1, wherein said supporting board is made from a metal.

6. The solar construction board of claim 1, wherein said first fluid medium is selected from a group consisting of water and air.

7. The solar construction board of claim 3, wherein said second fluid medium is selected from a group consisting of water and air.

8. A solar louver, comprising:
a frame having two opposite sides that extend in a longitudinal direction;
a plurality of aligned slanted boards which are mounted pivotally in said frame, which are aligned in a head-to-tail manner in said longitudinal direction, and which are turnable between opened and closed positions;
a plurality of solar cells which are respectively attached to said slanted boards;
a coupling unit pivoted to said slanted boards and movable in said longitudinal direction and in a transverse direction relative to said longitudinal direction so as to permit said slanted boards to be turnable between said opened and closed positions; and
a driving unit connected to said coupling unit so as to move said coupling unit in said longitudinal and transverse directions.

9. The solar louver of claim 8, wherein each of said slanted boards has two opposite sides in said longitudinal direction, and opposite first and second ends, said coupling unit including a pair of parallel elongated links that are respectively disposed at said opposite sides of said slanted boards and that are offset from said opposite sides of said frame in said transverse direction, said first ends of said slanted boards being pivoted to said links, said second ends of said slanted boards being pivoted to said frame, said coupling unit further including a lever that interconnects said driving unit and said links and that is turnable relative to said driving unit so as to move said links in said longitudinal and transverse directions, thereby moving said slanted boards between said opened and closed positions.

10. The solar louver of claim 9, further comprising a plurality of board shades and a plurality of board guides, each of said board shades extending inclinedly in a first inclined direction from said first end of a respective one of said slanted boards toward said second end of an adjacent one of said slanted boards, each of said board guides extending inclinedly in a second inclined direction from said second end of a respective one of said slanted boards toward said first end of an adjacent one of said slanted boards so that said board shade of each of said slanted boards and said board guide of an adjacent one of said slanted boards move toward each other when said slanted boards move from said opened position to said closed position.

11. The solar louver of claim 8, further comprising a solar energy collector that includes a plurality of heating tubes which are mounted respectively and securely on said slanted boards and which are filled with a first fluid medium therein so as to absorb solar energy and transfer the absorbed energy to said first fluid medium when exposed to solar radiation.

12. The solar louver of claim 8, further comprising a plurality of thermal insulator units that are mounted respectively and securely on said slanted boards and that are opposite to said solar cells so as to retard the radiation of heat from said slanted boards.

13. The solar louver of claim 12, wherein each of said thermal insulator units includes a plurality of juxtaposed conduits which are in fluid communication with each other and which are filled with a second fluid medium.

14. The solar louver of claim 11, wherein said first fluid medium is selected from a group consisting of water and air.

15. The solar louver of claim 13, wherein said second fluid medium is selected from a group consisting of water and air.

16. The solar louver of claim 8, wherein each of said slanted boards is made from a metal.

17. The solar louver of claim 9, further comprising opposite transparent first and second circular halves which respectively extend from said first and second ends of each of said slanted boards, said first circular half of each of said slanted boards complementing said second circular half of an adjacent one of said slanted boards to form a circular tube when said slanted boards are at said closed position, said solar louver further comprising a heating tube mounted in said circular tube.
